(19) United States
(12) Patent Application Publication
(10) Pub. No.: US 2012/0225518 A1
(43) Pub. Date: Sep. 6, 2012

(54) Method and Apparatus to Detect the Alignment of a Substrate

(75) Inventors: Luigi De Santi, Spresiano (IT); Andrea Baccini, Mignagola Di Carbonera (IT); Giorgio Cellere, Torri Di Quartesolo (vi) (IT); Marco Galiazzo, Padova (pd) (IT); Gianfranco Pasqualin, Spresiano (IT); Tommaso Vercesi, Treviso (IT)

(73) Assignee: APPLIED MATERIALS, INC., Santa Clara, CA (US)

(21) Appl. No.: 13/394,130

(22) PCT Filed: Sep. 2, 2010
(86) PCT No.: PCT/EP10/62835

§ 371 Date: May 21, 2012

(30) Foreign Application Priority Data
Sep. 3, 2009 (IT) UD2009A000148

(51) Int. Cl. H01L 31/18; B05D 5/12; B05C 11/00; B05D 5/00

(52) U.S. Cl. 438/73; 427/256; 427/58; 427/75; 118/712; 257/E31.001

(57) ABSTRACT

A method of detecting the alignment of a substrate during a sequence of printing steps, comprises detecting in a detection unit a position of at least one printing track that forms a printed pattern onto a surface of the substrate in a first printing station, determining a reference point in at least a portion of the printing track, comparing the actual position of the reference point with an expected or previously detected position of the reference point, determining an offset between the actual position and the expected or previously detected position of the reference point, adjusting the reciprocal position between the printing head of a second printing station and the substrate to account for the determined offset, and then printing a second pattern over the first pattern.

### CROSS-REFERENCE TO RELATED APPLICATIONS

This application claims benefit of International Patent Application Serial No. PCT/EP2010/062835 filed Sep. 2, 2010, which claims the benefit of Italian Patent Application serial number UD2009A000148, filed Sep. 3, 2009, which are both herein incorporated by reference.

### BACKGROUND OF THE INVENTION

1. Field of the Invention

Embodiments of the present invention generally relate to a method and an apparatus used to detect the alignment or position of a substrate during a sequence of printing steps. Embodiments of the present invention may be used to form conductive tracks on a substrate that is used to form a solar cell device.

2. Description of the Related Art

Printing processes are generally known in the art, in particular serigraph prints, in which one or more printing steps are used to deposit a printed material on a substrate, so as to define corresponding printed tracks.

It is also known that this technique is widely used for forming photovoltaic cells on a substrate, for example, a wafer or thin sheet of silicon. Typically, during parts of the photovoltaic formation process various printed tracks, for example conductive tracks, are deposited in different printing stations disposed in sequence one after the other.

The production of the photovoltaic cells, and consequently the relative printing processes, are subject to very precise tolerances, and it is therefore necessary to control the movement and position of the substrate between one printing station and the next.

One known technique for carrying out this type of control of the position of a pattern to be deposited on the substrate is to deposit, during the printing process and with the same print material, at least one marker element that is used for alignment. The position of each marker is then verified in the following station, to detect the actual alignment and positioning of the pattern on the substrate.

Although, this known technique has some disadvantages with regard to the need to deposit of the marker element, which includes an increase in the amount of print material used, an increase in the production times, and also the printed conductive tracks can affect the deposited pattern's electrical properties, such as creating an unwanted electrical short. Furthermore, the positioning of the marker element with respect to the conductive tracks may not be consistent from one printing head to another, due to possible lack of uniformity of the printing patterns formed in different printing heads, or slight intrinsic errors of each printing station. These types of errors can cause misalignment of the print tracks even if the markers are perfectly aligned with each other.

Moreover, the deposited markers reduce the usable surface area of the photovoltaic cell, which can affect the solar cell's ability to transform solar energy into electric energy.

These disadvantages of the state of the art can be found not only in silk-screen printing techniques but also in other types of printing, for example laser printing, ink jet or others.

Therefore, there is need for a method and an apparatus that can detect the alignment of the substrate in different operating stations in a simple, precise, reliable way that overcomes the disadvantages of the state of the art.

The Applicant has devised, tested and embodied the present invention to overcome the shortcomings of the state of the art and to obtain these and other purposes and advantages.

### SUMMARY OF THE INVENTION

The present invention is set forth and characterized in the independent claims, while the dependent claims describe other characteristics of the invention or variants to the main inventive idea.

In accordance with the above purpose, a method according to the present invention is applied to detect the alignment of a pattern on the substrate in a sequence of printing steps, in which a printed track is deposited on a surface of the substrate. In embodiments of the invention, a portion of the first printed track is used as a reference point, such as for example a crossing point of the printed tracks, to aid in the alignment and positioning of a second printed track that is to be deposited on the substrate in a subsequent printing step.

In particular, the method according to the invention for detecting the alignment of a substrate during a sequence of printing steps, comprises: detecting in a detection unit a position of at least one printing track, selected between a finger and a busbar, and forming a pattern printed onto a surface of the substrate in a first printing station, determining a reference point in at least a portion of said printing track, comparing in a detection unit the actual position of said reference point with an expected, or previously detected, position of said reference point; determining an offset between the actual position and the expected, or previously detected, position of said reference point; adjusting the reciprocal position between the printing head of a second printing station and the substrate for to account for the determined offset; and printing a second pattern onto the first pattern.

In particular, the method according to one embodiment of the present invention provides completing an identification step in which a detection unit is used to determine the position of the at least one reference point formed by at least a portion of the printed tracks disposed on a surface of a substrate, and printed in a first printing station, and then performing a comparison step in which the position is compared with an expected, or previously detected, position of the reference points on a print support.

In one embodiment of the present invention, the results of the comparison step are used to align the subsequent printing head according to the possible existing offset between the position detected and the position expected of the reference points formed by the printing tracks.

In another embodiment, the support is aligned with respect to the printing head, that remains fixed.

In one embodiment, the print track or tracks are used as a virtual reference point to determine the position of the substrate in the subsequent printing steps. Use of portions of the printed track as a virtual reference point thus allows for the reduction in the production times and the material, while also reducing the risk of compromising the integrity of the printed tracks. Furthermore, by using the virtual reference points found on the printed track(s), instead of applying an external marker element, one can be assured that any correction to the alignment made in a subsequent print station is directly related to the printed track(s) themselves, thus avoiding an error in the positioning of the marker element relative to the printed tracks.

In one embodiment, in which the substrate is for example, a silicon wafer that has printed tracks made of a conductor paste disposed thereon. The conductor paste is deposited in pattern that comprises an array of tracks of the conductor paste that are aligned substantially parallel to each other, known as “fingers”, and are connected at the ends by at least two transverse tracks known as “busbars.” In one embodiment, one or more reference points are formed at the intersection between the fingers and the busbars. In one embodiment, three reference points are formed and used by the control system to guarantee the correct positioning and alignment of the wafer in a subsequent printing station, based on the position of the fingers and the busbars printed in the previous station.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of an apparatus according to the present invention;

FIG. 2 is a schematic view of a possible printing conformation of a substrate;

FIG. 3 shows schematically a step of comparison in the method according to the present invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention may generally provide an apparatus 10 that is usable for aligning a printing device to a printed pattern formed on a substrate, such as a wafer 11, in an apparatus 100 for the production of photovoltaic cells. In this case, the apparatus 10 is used to detect the alignment of the wafer 11 which is positioned between two printing stations, respectively first station 12 and second station 13. In one embodiment, the apparatus 100 comprises a series of printing units that are found in each of the printing stations and are used in an apparatus 100 for the production of photovoltaic cells.

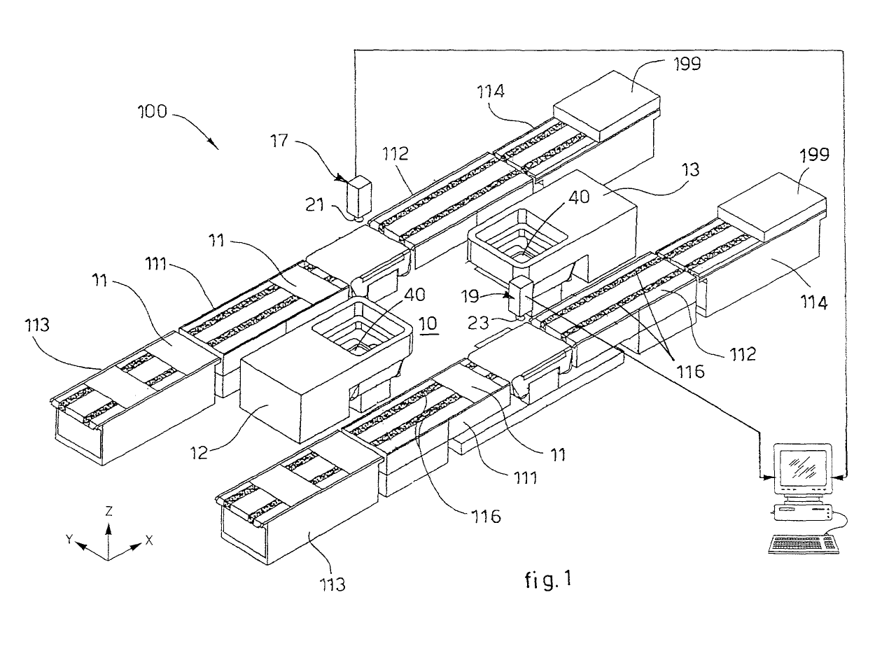

FIG. 1 is a schematic isometric view of one embodiment of the apparatus 100 in which the alignment apparatus 10 of the present invention may be used. In the embodiment, the apparatus 100 generally includes two conveyors 111, two printing stations 12, 13, two outgoing conveyors 112, and a command and control unit 20. The incoming conveyors 111 are configured in a parallel processing configuration so that each can receive an unprocessed wafer 11 from an input device, such as an input conveyor 113, and transfer each unprocessed wafer 11 to a couple of printing station 12, 13. Additionally, the outgoing conveyors 112 are configured in parallel so that each can receive a processed wafer 11 from a printing station 12, 13 and transfer each processed wafer 11 to a wafer removal device, such as an exit conveyor 114. In one embodiment, the input conveyor 113 and the exit conveyor 114 are automated substrate handling devices that are part of a larger production line, for example the Softline™ tool that is connected to the apparatus 100. In one embodiment, each exit conveyor 114 is adapted to transport processed wafers 11 through an oven 199 to cure material deposited on the wafer 11 via the printing stations 12, 13.

In one embodiment, the incoming conveyor 111 and outgoing conveyor 112 include at least one belt 116 to support and transport the wafers 11 to a desired position within the apparatus 100 by use of an actuator (not shown) that is in communication with the control unit 20. While FIG. 1 generally illustrates a two belt style substrate transferring system, other types of transferring mechanisms may be used to perform the same substrate transferring and positioning functions without varying from the basic scope of the invention.

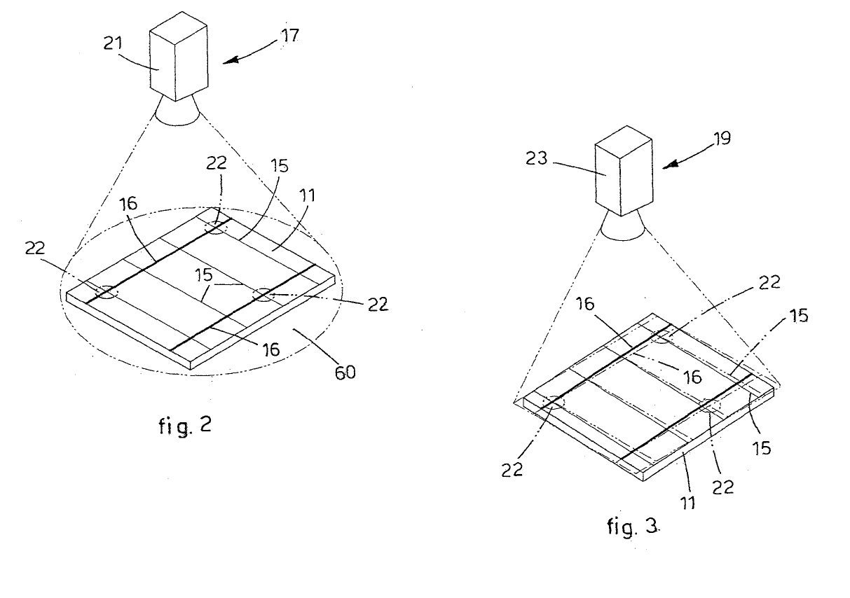

In particular, the upper surface of each wafer 11 is adapted to receive a plurality of print tracks, for example conductive tracks, that are used to collect a portion of the current generated by the formed solar cell device. In one example, shown in FIGS. 2 and 3, the printed tracks include a plurality of first tracks 15, called fingers, substantially parallel to each other, and second tracks 16, called busbars, which are substantially perpendicular to and intersect the first tracks 15 to form an electrical connection there between. While the printed pattern provided on each wafer 11 shown in FIGS. 2 and 3 has two printed tracks, this configuration in not intended to be limiting as to the scope of the invention described herein, since a single printed track or three or more different tracks can also be used depending on the operating requirements of the photovoltaic cell.

The printing stations 12 and 13 are configured to deposit different print layers or patterns on a surface of the wafer 11. In one example, the two printing heads 12 and 13 are specifically configured to deposit the first and second tracks 15 and 16, in different complementary patterns. In another example, the two printing heads 12 and 13 can be used to form multiple overlapping layers having the same printing pattern, and/or layers of materials having different physical or chemical properties.

However, in any case, the printed pattern obtained in the first printing station 12 must be accurately aligned, or in other way positioned in a strict correlation with the printed pattern obtained in the second printing station 13.

In one embodiment, the printing stations 12 and 13 include a plurality of actuators, for example stepper motors or servomotors, that are in communication with the command and control unit 20 and are used to adjust the position and/or angular orientation of a printing head 40 disposed within the relative station 12, 13 with respect to the wafer 11 being printed. In one embodiment, the printing head 40 is a metal sheet or plate with a plurality of features, such as holes, slots, or other apertures formed therethrough to define a pattern and placement of screen printed material (i.e., ink or paste) on a surface of the wafer 11. In general, the screen printed pattern that is to be deposited on the surface of the wafer 11 is aligned to the wafer 11 in an automated fashion by orienting the printing head in a desired position over the wafer surface using the actuators and information received by the unit 20, as disclosed hereinafter. In one embodiment, the printing stations 12 and 13 are adapted to deposit a metal containing or dielectric containing material on a wafer 11 having a width between about 125 mm and 156 mm and a length between about 70 mm and 156 mm. In one embodiment, the printing stations 12 and 13 are adapted to deposit a metal containing paste on the surface of the wafer 11 to form the metal contact structure on a surface of the wafer 11.

The apparatus 10 according to the present invention comprises an identification or detecting station 17 disposed immediately downstream of the first printing station 12, with respect to the direction of movement of the wafer 11, a comparison station 19 disposed immediately upstream of the second printing station 13 and a command and control unit 20 electronically connected at least to the identification station 17 and to the comparison station 19.

The control unit 20 may include a central processing unit (CPU) (not shown), memory (not shown), and support circuits (or I/O) (not shown). The CPU may be one of any form of computer processors that are used in industrial settings for controlling various chamber processes and hardware (e.g., conveyors, optical inspection assemblies, motors, fluid delivery hardware, etc.) and monitor the system and chamber processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the control unit 20 determines which tasks are performable on a substrate. Preferably, the program is software readable by the control unit 20, which includes code to generate and store at least substrate positional information, the sequence of movement of the various controlled components, substrate optical inspection system information, and any combination thereof.

It should be noted that, while not shown in the drawings, one or more processing chambers can be disposed between the two printing stations 12 and 13 to perform various different operating steps that are complementary to the printing process, such as drying, doping the printed material, high-temperature annealing, alignment on the pattern obtained, printing metal or other similar function.

The identification station 17 comprises a video camera 21, for example a CCD camera, disposed above and substantially perpendicular to a surface of the wafer 11 that is parallel to a transfer plane 60 on which the wafer 11 passes after exiting the first printing station 12.

The video camera 21 is suitable to detect an image of the upper surface of the wafer 11 that has the first and second tracks 15 and 16 disposed thereon by a printing process performed in the first printing station 12. The detected image is processed by the control unit 20 so as to detect at least three crossing points between the first tracks 15 and the second tracks 16, and so as to establish three reference points 22 provided directly by the tracks 15, 16 themselves, without using the prior art marker elements or fiducials. In one example, as shown in FIGS. 2 and 3, the reference points 22 are schematically represented as circular regions bounded by a discontinuous line. In one embodiment, three reference points 22 are detected, to identify the positioning of the formed pattern on the wafer 11. In some configurations, it may be desirable to detect fewer or more than three reference points 22.

The data contained in an image, which contains the virtual reference points 22, is sent from the video camera 21 by means of the command and control unit 20 to the comparison station 19.

The comparison station 19 comprises a video camera 23, for example a CCD camera, also disposed above and perpendicular to the transfer plane on which the wafer 11 passes, such as at the entrance to the second printing station 13.

In one embodiment, the video camera 23 is generally suitable to project virtually the image of the wafer 11 detected by the video camera 21 with the current position of the substrate under the video camera 23 by use of the reference points 22.

In this way, a movement of the wafer 11, or of its support, between the identification station 17 and the comparison station 19 can be detected in order to take account of it during the subsequent step of alignment.

In one embodiment, moreover, the position of the reference points 22 identified on the printed tracks 15 and 16 is compared with a known position, and sent to the control unit 20 in order to adjust the subsequent printing head in the printing station 13.

In FIG. 3, a virtually projected image is shown by a series of dashed lines, simply to schematically illustrate the functioning thereof and not represent the real operating conditions.

Therefore, by comparing the virtual image detected by the video camera 21 and by the video camera 23 the deviation between the reference points 22 are detected, to determine the difference in the position of the wafer 11 currently under the video camera 23 with the data collected by the video camera 21 positioned at the exit from the first printing station 12. In one embodiment, the deviation is directly detected and determined using the reference points 22 formed at the intersection of the first and second tracks 15 and 16, without needing other reference points.

In one embodiment, a software provided in the control unit 20 makes the comparison between the data detected in the two stations 17 and 19.

The value of the deviation detected is sent to the command and control unit 20, which processes the datum according to programmed or programmable tolerance parameters, and possibly commands a station for the correction of the position of the wafer 11, of a substantially known type and not shown in the drawings, to position and align the wafer 11 correctly before the second printing station 13.

It is clear, however, that modifications and/or additions of parts or steps may be made to the method and apparatus 10 as described heretofore, without departing from the field and scope of the present invention.

For example, it comes within the field of the present invention to provide a method and an apparatus in which the wafer 11 remains always stationary in its initial position and the printing stations 12 and 13 are each positioned sequentially over the wafer 11 to deposit the relative print tracks 15 and 16.

In this embodiment, the detection of the reference points 22 and the subsequent comparison with the expected position of the wafer 11 is used to correct the position of the second printing station 13 with respect to the wafer 11, so as to guarantee the correct alignment of the print tracks 15 and 16 printed by the relative printing stations 12 and 13.

In this embodiment it is advantageous, but not necessary, to provide a single detection unit which functionally comprises the characteristics both of the identification station 17 and also of the comparison station 19, so that it can carry out both the operations to detect the reference points 22 and also to compare the position of these reference points 22 to the expected positions thereof.

It is also clear that, although the present invention has been described with reference to specific examples, a person of skill in the art shall certainly be able to achieve many other equivalent forms of method and apparatus to detect the alignment of a substrate, having the characteristics as set forth in the claims and hence all coming within the field of protection defined thereby.

1-13. (canceled)

14. A method of aligning a position of a substrate during a printing process, comprising:
depositing one or more print tracks in a first pattern on a surface of the substrate, wherein the one or more print tracks comprises one or more reference points;
detecting a reference position of the one or more reference points on the surface of the substrate;
transferring the substrate to a printing position in a printing station;
comparing the printing position of the one or more reference points with an expected position within the printing station or the detected reference position of the one or more reference points;
determining an offset between the printing position of the one or more reference points and the expected position or the reference position;
moving the substrate or a printing head within the printing station a distance equal to the offset; and
depositing one or more print tracks in a second pattern on the surface of the substrate after moving the substrate using the printing head.

15. The method of claim 14, wherein the first pattern and the second pattern comprise a plurality of tracks of a conductor paste.

16. The method of claim 14, wherein the first pattern comprises a plurality of tracks of substantially parallel fingers.

17. The method of claim 16, wherein the second pattern comprises a plurality of busbars.

18. The method of claim 14, wherein the second pattern disposed on at least a portion of the first pattern.

19. The method of claim 14, further comprising:
detecting the reference position of the one or more reference points on the surface of the substrate using a first detection station; and
detecting the printing position of the one or more reference points on the surface of the substrate using a second detection station.

20. The method of claim 14, wherein
the detecting the reference position of the one or more reference points on the surface of the substrate and the detecting the second position of the one or more reference points on the surface of the substrate are performed using a single detection unit.

21. The method of claim 20, wherein the single detection unit comprises an identification member and a comparison member.

22. The method of claim 14, wherein the one or more print tracks comprises conductive materials for collecting a portion of a current generated by solar cell devices formed using the substrate.

23. The method of claim 14, wherein, according to the result of the comparison, the position of the substrate relative to the printing head is corrected and adjusted by use of the determined offset.

24. The method of claim 14, wherein
the substrate is a wafer used for forming photovoltaic cells,
the first pattern comprises print tracks substantially parallel to each other, and
the one or more reference points are formed at least by a part of the first pattern or the second pattern.

25. The method of claim 14, wherein the one or more reference points comprise at least three reference points.

26. An apparatus for processing a substrate, comprising:
a first printing station configured to deposit a first print track on the surface of a substrate;
an identification member that is configured to detect the reference position of one or more reference points formed by at least a portion of the first print track;
a second printing station configured to deposit a second print track on the surface of the substrate; and
a comparison member having a camera that is configured to detect the printing position of the one or more reference points formed by at least a portion of the first print track or the second print track, and compare the printing position of the one or more reference points with an expected position or the reference position.

27. The apparatus of claim 26, further comprising:
a control unit adapted to compare a reference position of one of the one or more reference points on the surface of the substrate with a printing position of one of the one or more reference points on the surface of the substrate.

28. The apparatus of claim 27, wherein the identification member and the comparison member are connected to the control unit.

29. The apparatus of claim 26, wherein the identification member comprises a first video camera positioned over the substrate that is configured to determine the reference position.

30. The apparatus of claim 29, wherein the camera of the comparison member comprises a second video camera, and the comparison member is configured to compare the virtual image data detected by the first video camera with an image of the substrate detected by the second video camera.

31. An apparatus for processing a substrate, comprising:
a control unit;
a first printing station coupled to the control unit, and configured to deposit a print track on the surface of a substrate; and
a detection unit coupled to the control unit, comprising:
an identification member configured to detect the reference position of one or more reference points formed by at least a portion of the print track; and
a comparison member configured compare the reference position with an expected position to determine an offset.
